(19) United States
(12) Patent Application Publication
(10) Pub. No.: US 2010/0243048 A1
(43) Pub. Date: Sep. 30, 2010

(54) METAL PASTES AND USE THEREOF IN THE PRODUCTION OF SILICON SOLAR CELLS

(75) Inventors: Giovanna Laudisio, Bristol (GB); Richard John Sheffield Young, Somerset (GB); Peter James Willmott, South Gloucestershire (GB); Kenneth Warren Hang, Hillsborough, NC (US)

Correspondence Address: E I DU PONT DE NEMOURS AND COMPANY;LEGAL PATENT RECORDS CENTER, BARLEY MILL PLAZA 25/1122B, 4417 LANCASTER PIKE, WILMINGTON, DE, 19805, US

(73) Assignee: E. I. DU PONT DE NEMOURS AND COMPANY, Wilmington (DE)

(21) Appl. No.: 12/749,800

(22) Filed: Mar. 30, 2010

Related U.S. Application Data
(60) Provisional application No. 61/164,569, filed on Mar. 30, 2009.

(51) Int. Cl. H01L 31/0224; H01L 21/3205; H01B 5/00; H01B 1/02; H01B 1/22

(52) U.S. Cl. 136/256; 438/666; 174/126.1; 252/512; 252/513; 252/514; 257/E21.295; 257/E31.124

(57) ABSTRACT

Metal pastes comprising (a) at least one electrically conductive metal powder selected from the group consisting of silver, copper and nickel, (b) at least one lead-free glass frit with a softening point temperature in the range of 550 to 611° C. and containing 11 to 33 wt.-% of SiO₂, >0 to 7 wt.-% of Al₂O₃ and 2 to 10 wt.-% of B₂O₃ and (c) an organic vehicle.

### FIELD OF THE INVENTION

The present invention is directed to metal pastes and their use in the production of silicon solar cells.

### TECHNICAL BACKGROUND OF THE INVENTION

A conventional solar cell structure with a p-type base has a negative electrode that is typically on the front-side or sun side of the cell and a positive electrode on the back-side. It is well known that radiation of an appropriate wavelength falling on a p-n junction of a semiconductor body serves as a source of external energy to generate electron-hole pairs in that body. The potential difference that exists at a p-n junction, causes holes and electrons to move across the junction in opposite directions, thereby giving rise to flow of an electric current that is capable of delivering power to an external circuit. Most solar cells are in the form of a silicon wafer that has been metalized, i.e., provided with metal contacts which are electrically conductive.

Most electric power-generating solar cells currently used are silicon solar cells. Electrodes in particular are made by using a method such as screen printing from metal pastes.

The production of a silicon solar cell typically starts with a p-type silicon substrate in the form of a silicon wafer on which an n-type diffusion layer of the reverse conductivity type is formed by the thermal diffusion of phosphorus (P) or the like. Phosphorus oxychloride (POCl₃) is commonly used as the gaseous phosphorus diffusion source, other liquid sources are phosphoric acid and the like. In the absence of any particular modification, the diffusion layer is formed over the entire surface of the silicon substrate. The p-n junction is formed where the concentration of the p-type dopant equals the concentration of the n-type dopant; conventional cells that have the p-n junction close to the sun side, have a junction depth between 0.05 and 0.5 μm.

After formation of this diffusion layer excess surface glass is removed from the rest of the surfaces by etching by an acid such as hydrofluoric acid.

Next, an ARC layer (antireflective coating layer) of TiOₓ, SiOₓ, TiOₓ/SiOₓ, or, in particular, SiNₓ or Si₃N₄ is formed on the n-type diffusion layer to a thickness of between 0.05 and 0.1 μm by a process, such as, for example, plasma CVD (chemical vapor deposition).

A conventional solar cell structure with a p-type base typically has a negative grid electrode on the front-side or sun side of the cell and a positive electrode on the back-side. The grid electrode is typically applied by screen printing and drying a front-side silver paste (front electrode forming silver paste) on the ARC layer on the front-side of the cell. The front-side grid electrode is typically screen printed in a so-called H pattern which comprises (i) thin parallel finger lines (collector lines) and (ii) two busbars intersecting the finger lines at right angle. In addition, a back-side silver or silver/aluminum paste and an aluminum paste are screen printed (or some other application method) and successively dried on the back-side of the substrate. Normally, the back-side silver or silver/aluminum paste is screen printed onto the silicon wafer's back-side first as two parallel busbars or as rectangles (tabs) ready for soldering interconnection strings (presoldered copper ribbons). The aluminum paste is then printed in the bare areas with a slight overlap over the back-side silver or silver/aluminum. In some cases, the silver or silver/aluminum paste is printed after the aluminum paste has been printed. Firing is then typically carried out in a belt furnace for a period of 1 to 5 minutes with the wafer reaching a peak temperature in the range of 700 to 900° C. The front grid electrode and the back electrodes can be fired sequentially or co fired.

The aluminum paste is generally screen printed and dried on the back-side of the silicon wafer. The wafer is fired at a temperature above the melting point of aluminum to form an aluminum-silicon melt, subsequently, during the cooling phase, an epitaxially grown layer of silicon is formed that is doped with aluminum. This layer is generally called the back surface field (BSF) layer. The aluminum paste is transformed by firing from a dried state to an aluminum back electrode. The back-side silver or silver/aluminum paste is fired at the same time, becoming a silver or silver/aluminum back electrode. During firing, the boundary between the back-side aluminum and the back-side silver or silver/aluminum assumes an alloy state, and is connected electrically as well. The aluminum electrode accounts for most areas of the back electrode, owing in part to the need to form a p+ layer. A silver or silver/aluminum back electrode is formed over portions of the back-side (often as 2 to 6 mm wide busbars) as an electrode for interconnecting solar cells by means of pre-soldered copper ribbon or the like. In addition, the front-side silver paste printed as front-side grid electrode sinters and penetrates through the ARC layer during firing, and is thereby able to electrically contact the n-type layer. This type of process is generally called “firing through”.

WO 92/22928 discloses a process wherein the front-side grid electrode is printed in two steps; printing of the finger lines and of the busbars is decoupled. Whereas the finger lines are printed from a silver paste which is capable of firing through the ARC coating, this is not the case for the silver paste used for printing the busbars. The silver paste used for printing the busbars has no fire through capability. After firing a grid electrode is obtained consisting of fired-trough finger lines and so-called non-contact busbars (floating busbars, busbars which have not fired through the ARC layer). The advantage of the grid electrode only the finger lines of which are fired through is a reduction of recombination of holes and electrons at the metal/semiconductor interface. The reduction of recombination results in an increase of open circuit voltage and thus an increase of electrical yield of the silicon solar cell having such type of front-side grid electrode.

There is a desire to provide thick film conductive compositions with poor or even no fire through capability and which allow for the production of busbars without or with only poor contact with the silicon substrate, with improved solder leach resistance and good adhesion to the ARC layer on the front-side surface of a silicon solar cell. Good adhesion means a prolonged durability or service life of the silicon solar cell.

### SUMMARY OF THE INVENTION

The present invention relates to thick film conductive compositions comprising (a) at least one electrically conductive metal powder selected from the group consisting of silver, copper and nickel, (b) at least one lead-free glass frit with a softening point temperature (glass transition temperature, determined by differential thermal analysis DTA at a heating rate of 10 K/min) in the range of 550 to 611° C. and containing 11 to 33 wt.-% (weight-%) of SiO₂, >0 to 7 wt.-% of Al₂O₃ and 2 to 10 wt.-% of B₂O₃ and (c) an organic vehicle.

### DETAILED DESCRIPTION OF THE INVENTION

The thick film conductive compositions of the present invention take the form of metal pastes that can be applied by printing, in particular, screen printing. In the following description and in the claims the thick film conductive compositions will also be called “metal pastes”.

The metal pastes of the present invention comprise at least one electrically conductive metal powder selected from the group consisting of silver, copper and nickel. Silver powder is preferred. The metal or silver powder may be uncoated or at least partially coated with a surfactant. The surfactant may be selected from, but is not limited to, stearic acid, palmitic acid, lauric acid, oleic acid, capric acid, myristic acid and linolic acid and salts thereof, for example, ammonium, sodium or potassium salts.

The average particle size of the electrically conductive metal powder or, in particular, silver powder is in the range of, for example, 0.5 to 5 μm. The total content of the electrically conductive metal powder or, in particular, silver powder in the metal pastes of the present invention is, for example, 50 to 92 wt.-%, or, in an embodiment, 65 to 84 wt.-%.

In the description and the claims the term “average particle size” is used. It means the mean particle diameter (d50) determined by means of laser scattering. All statements made in the present description and the claims in relation to average particle sizes relate to average particle sizes of the relevant materials as are present in the metal pastes.

In general the metal pastes of the present invention comprise only the at least one electrically conductive metal powder selected from the group consisting of silver, copper, and nickel. However, it is possible to replace a small proportion of the electrically conductive metal selected from the group consisting of silver, copper and nickel by one or more other particulate metals. The proportion of such other particulate metal(s) is, for example, 0 to 10 wt. %, based on the total of particulate metals contained in the conductive metal paste.

The metal pastes of the present invention comprise one or more lead-free glass frits as inorganic binder. The at least one lead-free glass frit has a softening point temperature in the range of 550 to 611° C. and contains 11 to 33 wt.-% of SiO₂, >0 to 7 wt.-%, in particular 5 to 6 wt.-% of Al₂O₃ and 2 to 10 wt.-% of B₂O₃. The weight percentages of SiO₂, Al₂O₃ and B₂O₃ do not total 100 wt.-% and the missing wt.-% are in particular contributed by one or more other oxides, for example, alkali metal oxides like Na₂O, alkaline earth metal oxides like MgO and metal oxides like Bi₂O₃, TiO₂ and ZnO.

In an embodiment the at least one lead-free glass frit contains 40 to 73 wt.-%, in particular 48 to 73 wt.-% of Bi₂O₃. Here, the weight percentages of Bi₂O₃, SiO₂, Al₂O₃ and B₂O₃ may or may not total 100 wt.-%. In case they do not total 100 wt.-% the missing wt.-% may in particular be contributed by one or more other oxides, for example, alkali metal oxides like Na₂O, alkaline earth metal oxides like MgO and metal oxides like TiO₂ and ZnO.

The average particle size of the at least one lead-free glass frit is in the range of, for example, 0.5 to 4 μm. The total content of the at least one lead-free glass frit in the metal pastes of the present invention is, for example, 0.25 to 8 wt.-%, or, in an embodiment, 0.8 to 3.5 wt.-%. The metal pastes of the present invention do not contain any lead-containing glass frit.

The preparation of the lead-free glass frits is well known and consists, for example, in melting together the constituents of the lead-free glass in the form of the oxides of the constituents and pouring such molten composition into water to form the frit. As is well known in the art, heating may be conducted to a peak temperature and for a time such that the melt becomes entirely liquid and homogeneous.

The glass may be milled in a ball mill with water or inert low viscosity, low boiling point organic liquid to reduce the particle size of the frit and to obtain a frit of substantially uniform size. It may then be settled in water or said organic liquid to separate fines and the supernatant fluid containing the fines may be removed. Other methods of classification may be used as well.

The metal pastes of the present invention comprise an organic vehicle. A wide variety of inert viscous materials can be used as organic vehicle. The organic vehicle may be one in which the particulate constituents (electrically conductive metal powder, lead-free glass frit) are dispersible with an adequate degree of stability. The properties, in particular, the rheological properties, of the organic vehicle may be such that they lend good application properties to the metal pastes, including: stable dispersion of insoluble solids, appropriate viscosity and thixotropy for application, in particular, for screen printing, appropriate wet ability of the ARC layer on the front-side of a silicon wafer and of the paste solids, a good drying rate, and good firing properties. The organic vehicle used in the metal pastes of the present invention may be a nonaqueous inert liquid. The organic vehicle may be an organic solvent or an organic solvent mixture; in an embodiment, the organic vehicle may be a solution of organic polymer(s) in organic solvent(s). Use can be made of any of various organic vehicles, which may or may not contain thickeners, stabilizers and/or other common additives. In an embodiment, the polymer used as constituent of the organic vehicle may be ethyl cellulose. Other examples of polymers which may be used alone or in combination include ethylhydroxyethyl cellulose, wood rosin, phenolic resins and poly(meth)acrylates of lower alcohols. Examples of suitable organic solvents comprise ester alcohols and terpenes such as alpha- or beta-terpineol or mixtures thereof with other solvents such as kerosene, dibutylphthalate, diethylene glycol butyl ether, diethylene glycol butyl ether acetate, hexylene glycol and high boiling alcohols. In addition, volatile organic solvents for promoting rapid hardening after application of the metal pastes can be included in the organic vehicle. Various combinations of these and other solvents may be formulated to obtain the viscosity and volatility requirements desired.

The ratio of organic vehicle in the metal pastes of the present invention to the inorganic components (electrically conductive metal powder plus lead-free glass frit plus optionally present other inorganic additives) is dependent on the method of applying the metal pastes and the kind of organic vehicle used, and it can vary. Usually, the metal pastes will contain 58-95 wt.-% of inorganic components and 5-42 wt.-% of organic vehicle.

The metal pastes of the present invention are viscous compositions, which may be prepared by mechanically mixing the electrically conductive metal powder(s) and the lead-free glass frit(s) with the organic vehicle. In an embodiment, the manufacturing method power mixing, a dispersion technique that is equivalent to the traditional roll milling, may be used; roll milling or other mixing technique can also be used.

The metal pastes of the present invention can be used as such or may be diluted, for example, by the addition of additional organic solvent(s); accordingly, the weight percentage of all the other constituents of the metal pastes may be decreased.

The metal pastes of the present invention may be used in the production of front-side grid electrodes of silicon solar cells or respectively in the production of silicon solar cells. Therefore the invention relates also to such production processes and to front-side grid electrodes and silicon solar cells made by said production processes.

The process for the production of a front-side grid electrode may be performed by (1) providing a silicon wafer having an ARC layer on its front-side, (2) printing, in particular, screen printing and drying a metal paste of the present invention on the ARC layer on the front-side of the silicon wafer to form two or more parallel busbars, (3) printing, in particular, screen printing and drying a metal paste with fire through capability on the ARC layer to form thin parallel finger lines intersecting the busbars at right angle, and (4) firing the printed and dried metal pastes. As a result of the process a front-side grid electrode consisting of fired-through finger lines and non-contact busbars is obtained.

The process for the production of such front-side grid electrode may however also be performed in the opposite sequence, i.e. by (1) providing a silicon wafer having an ARC layer on its front-side, (2) printing, in particular, screen printing and drying a metal paste with fire through capability on the ARC layer on the front-side of the silicon wafer to form thin parallel finger lines, (3) printing, in particular, screen printing and drying a metal paste of the present invention on the ARC layer to form two or more parallel busbars intersecting the finger lines at right angle and (4) firing the printed and dried metal pastes. As a result of the process a front-side grid electrode consisting of fired-through finger lines and non-contact busbars is obtained.

In step (1) of the processes disclosed in the two preceding paragraphs a silicon wafer having an ARC layer on its front-side is provided. The silicon wafer is a conventional mono- or polycrystalline silicon wafer as is conventionally used for the production of silicon solar cells, i.e. it typically has a p-type region, an n-type region and a p-n junction. The silicon wafer has an ARC layer, for example, of TiOₓ, SiOₓ, TiOₓ/SiOₓ, or, in particular, SiNₓ or Si₃N₄ on its front-side. Such silicon wafers are well known to the skilled person; for brevity reasons reference is made to the section “TECHNICAL BACKGROUND OF THE INVENTION”. The silicon wafer may already be provided with the conventional back-side metallizations, i.e. with a back-side aluminum paste and a back-side silver or back-side silver/aluminum paste as described above in the section “TECHNICAL BACKGROUND OF THE INVENTION”. Application of the back-side metal pastes may be carried out before or after the front-side grid electrode is finished. The back-side pastes may be individually fired or co fired or even be co fired with the front-side metal pastes printed on the ARC layer in steps (2) and (3).

In the description and the claims the term “metal paste with fire through capability” is used. It means a conventional metal paste that fires through an ARC layer making electrical contact with the surface of the silicon substrate, as opposed to the metal pastes of the present invention which do not. Such metal pastes comprise in particular silver pastes with fire through capability; they are known to the skilled person and they have been described in various patent documents, an example of which is US 2006/0231801 A1.

After application of the metal pastes in steps (2) and (3) they are dried, for example, for a period of 1 to 100 minutes with the silicon wafer reaching a peak temperature in the range of 100 to 300° C. Drying can be carried out making use of, for example, belt, rotary or stationary driers, in particular, IR (infrared) belt driers.

The firing step (4) following steps (2) and (3) is a co firing step. It is however also possible, although not preferred, to perform an additional firing step between steps (2) and (3). Anyway, as a result of the production processes comprising steps (1) to (4) a grid electrode consisting of fired-through finger lines and non-contact busbars is produced on the ARC layer on the front-side of the silicon wafer. The parallel fired-through finger lines have a distance between each other of, for example, 2 to 5 mm, a layer thickness of, for example, 3 to 30 μm and a width of, for example, 50 to 150 μm. The fired but non-contact busbars have a layer thickness of, for example, 20 to 50 μm and a width of, for example, 1 to 3 mm.

The firing of step (4) may be performed, for example, for a period of 1 to 5 minutes with the silicon wafer reaching a peak temperature in the range of 700 to 900° C. The firing can be carried out making use of, for example, single or multi-zone belt furnaces, in particular, multi-zone IR belt furnaces. The firing may happen in an inert gas atmosphere or in the presence of oxygen, for example, in the presence of air. During firing the organic substance including non-volatile organic material and the organic portion not evaporated during the drying may be removed, i.e. burned and/or carbonized, in particular, burned and the glass frit sinters with the electrically conductive metal powder. Whereas the metal paste used for printing the parallel thin finger lines etches the ARC layer and fires through resulting in the finger lines making electrical contact with the silicon substrate, this is not the case for the metal paste of the present invention used for printing the busbars. The busbars remain as “non-contact” busbars after firing, i.e. the ARC layer survives at least essentially between the busbars and the silicon substrate.

The grid electrodes or the silicon solar cells produced by the processes using the metal pastes of the present invention exhibit the advantageous electrical properties associated with non-contact busbars or busbars having only poor contact with the silicon substrate as opposed to fired through busbars. The busbars produced by the processes of the present invention are distinguished by good solder leach resistance and good adhesion to the front-side or, more precisely, to the ARC layer on the front-side of a silicon solar cell.

### EXAMPLES

The Examples cited here relate to metal pastes fired onto conventional solar cells having a p-type silicon base and a silicon nitride ARC layer on the front-side n-type emitter.

The discussion below describes how a solar cell is formed utilizing a composition of the present invention and how it is tested for its technological properties.

### (1) Manufacture of Solar Cell

A solar cell was formed as follows:

(i) On the front face of a Si substrate (200 μm thick multicrystalline silicon wafer of area 243 cm², p-type (boron) bulk silicon, with an n-type diffused POCl₃ emitter, surface texturized with acid, SiNₓ ARC layer on the wafer's emitter applied by CVD) having a 30 μm thick aluminum electrode (screen-printed from PV381 Al composition commercially available from E. I. Du Pont de Nemours and Company) and two 5 mm wide busbars (screen-printed from PV505, an Ag composition commercially available from E. I. Du Pont de Nemours and Company and overlapping with the aluminum film for 1 mm at both edges to ensure electrical continuity) on its back surface, a front-side silver paste (PV142 commercially available from E. I. Du Pont de Nemours and Company) was screen-printed and dried as 100 μm wide and 20 μm thin parallel finger lines having a distance of 2.2 mm between each other. Then a front-side busbar silver paste was screen-printed as two 2 mm wide and 25 μm thick parallel busbars intersecting the finger lines at right angle. All metal pastes were dried before cofiring.

The example front-side busbar silver paste comprised 81 wt. % silver powder (average particle size 2 μm), 19 wt. % organic vehicle (organic polymeric resins and organic solvents) plus glass frit (average particle size 1.8 μm). The glass frit had a softening point temperature of 557° C. and it consisted of 11.9 wt.-% SiO₂, 6.2 wt.-% Al₂O₃, 9.7 wt.-% B₂O₃ and 72.2 wt.-% Bi₂O₃.

(ii) The printed wafers were then fired in a Despatch furnace at a belt speed of 3000 mm/min with zone temperatures defined as zone 1=500° C., zone 2=525° C., zone 3=550° C. zone 4=600° C., zone 5=925° C. and the final zone set at 890° C., thus the wafers reaching a peak temperature of 800° C. After firing, the metallized wafers became functional photovoltaic devices.

Measurement of the electrical performance and fired adhesion between the front-side busbars and the SiNₓ ARC layer was undertaken. Furthermore the fire through capability was determined.

### (2) Test Procedures

### Efficiency

The solar cells formed according to the method described above were placed in a commercial I-V tester (supplied by h.a.l.m. elektronik GmbH) for the purpose of measuring light conversion efficiencies. The lamp in the I-V tester simulated sunlight of a known intensity (approximately 1000 W/m²) and illuminated the emitter of the cell. The metallizations on the cells were subsequently contacted by electrical probes. The photocurrent (Voc, open circuit voltage; Isc, short circuit current) generated by the solar cells was measured over a range of resistances to calculate the I-V response curve.

### Fire-Through Capability

The front-side busbar silver paste was screen printed and fired in the above mentioned H pattern comprising finger lines and busbars (no use of PV142 front-side silver paste for finger line printing!). Then the efficiency of the cell was measured. In case of a front-side busbar paste without or with only poor fire through capability the electrical efficiency of the solar cell is in the range of 0 to 4% (=no or only limited fire through; today's state-of-the-art solar cells reach an electrical efficiency in the range of 15 to 17%).

### Adhesion Test

For the adhesion test both the ribbon and the front-side busbars were wetted with liquid flux and soldered using a manual soldering iron moving along the complete length of the wafer at a constant rate. The soldering iron tip was adjusted to specified temperatures of 325° C. There was no pre-drying or pre-heating of the fluxes prior to soldering.

Flux and solder ribbon used in this test were Kester® 952S and 62Sn-36Pb-2Ag (metal alloy consisting of 62 wt.-% tin, 36 wt.-% lead and 2 wt.-% silver) respectively.

Adhesion was measured using a Mecmesin adhesion tester by pulling on the solder ribbon at multiple points along the busbar at a speed of 100 mm/s and a pull angle of 90°. The force to remove the busbar was measured in grams.

Examples A to D cited in Table 1 illustrate the electrical properties of the front-side busbar silver pastes as a function of the proportion of the glass frit they contain. The data in Table 1 confirms that the electrical performance of the solar cells made using front-side busbar silver pastes according to Examples A to D is good; open circuit voltage Voc is high, the adhesion is sufficient and the resistivity is low.

TABLE 1

| | wt.-% | Voc | Isc | Fire | Adhesion | Resistivity |
|---|---|---|---|---|---|---|
| Example | glass frit | (mV) | (A) | through | (grams) | (μOhm · cm) |
| A | 0.25 | 614.3 | 8.04 | limited | 279 | 2.007 |
| B | 0.5 | 613.3 | 8.08 | limited | 353 | 2.246 |
| C | 1 | 614.3 | 8.07 | limited | 627 | 2.189 |
| D | 2 | 614.6 | 8.08 | limited | 756 | 2.092 |

What is claimed is:

1. A metal paste comprising (a) at least one electrically conductive metal powder selected from the group consisting of silver, copper and nickel, (b) at least one lead-free glass frit with a softening point temperature in the range of 550 to 611° C. and comprising 11 to 33 wt.-% of SiO₂, >0 to 7 wt.-% of Al₂O₃ and 2 to 10 wt.-% of B₂O₃ and (c) an organic vehicle.

2. The metal paste of claim 1, wherein the at least one lead-free glass frit contains 40 to 73 wt.-% of Bi₂O₃.

3. The metal paste of claim 1, wherein the total content of the at least one electrically conductive metal powder is 50 to 92 wt.-%.

4. The metal paste of claim 1, wherein the at least one electrically conductive metal powder is silver powder.

5. The metal paste of claim 1, wherein the total content of the at least one lead-free glass frit is 0.25 to 8 wt.-%.

6. The metal paste of claim 1 comprising 58-95 wt.-% of inorganic components and 5-42 wt.-% of organic vehicle.

7. A process for the production of a front-side grid electrode comprising the steps:
(1) providing a silicon wafer having an ARC layer on its front-side,
(2) printing and drying the metal paste of claim 1 on the ARC layer on the front-side of the silicon wafer to form two or more parallel busbars,
(3) printing and drying a metal paste with fire through capability on the ARC layer to form thin parallel finger lines intersecting the busbars at right angle, and
(4) firing the printed and dried metal pastes.

8. A process for the production of a front-side grid electrode comprising the steps:
(1) providing a silicon wafer having an ARC layer on its front-side,
(2) printing and drying a metal paste with fire through capability on the ARC layer on the front-side of the silicon wafer to form thin parallel finger lines,
(3) printing and drying the metal paste of claim 1 on the ARC layer to form two or more parallel busbars intersecting the finger lines at right angle, and
(4) firing the printed and dried metal pastes.

9. The process of claim 7, wherein the ARC layer is selected from the group consisting of TiOₓ, SiOₓ, TiOₓ/SiOₓ, SiNₓ or Si₃N₄ ARC layers.

10. A front-side grid electrode produced according to the process of claim 7.

11. A silicon solar cell comprising a silicon wafer having an ARC layer on its front-side and a front-side grid electrode of claim 10.

12. The process of claim 8, wherein the ARC layer is selected from the group consisting of TiOₓ, SiOₓ, TiOₓ/SiOₓ, SiNₓ or Si₃N₄ ARC layers.

13. A front-side grid electrode produced according to the process of claim 8.

14. A silicon solar cell comprising a silicon wafer having an ARC layer on its front-side and a front-side grid electrode of claim 13.
